(19) United States
(12) Patent Application Publication
(10) Pub. No.: US 2021/0066086 A1
(43) Pub. Date: Mar. 4, 2021

(54) CHEMICAL MECHANICAL POLISHING METHOD AND METHOD OF MANUFACTURING SEMICONDUCTOR DEVICE AND POLISHING PAD AND CHEMICAL MECHANICAL POLISHING DEVICE

(71) Applicant: SAMSUNG ELECTRONICS CO., LTD., Suwon-si (KR)

(72) Inventors: Do Yoon KIM, Hwaseong-si (KR); Kenji TAKAI, Hwaseong-si (KR); Deuk Kyu MOON, Seoul (KR); Min Hee YOON, Hwaseong-si (KR); Moon Il JUNG, Suwon-si (KR)

(21) Appl. No.: 16/867,715

(22) Filed: May 6, 2020

(30) Foreign Application Priority Data
Aug. 26, 2019 (KR) 10-2019-0104348

(51) Int. Cl. H01L 21/306; C09G 1/02; B24B 37/015; B24B 37/22

(52) U.S. Cl. CPC H01L 21/30625; B24B 37/22; B24B 37/015; C09G 1/02

(57) ABSTRACT

A chemical mechanical polishing method including preparing a polishing pad including a polishing surface having an elastic modulus at room temperature of about 300 MPa to about 400 MPa, positioning a semiconductor structure having a surface, wherein the surface and the polishing surface of the polishing pad face each other, supplying polishing slurry including nano-abrasive having an average particle diameter of less than about 10 nm between the surface of the semiconductor structure and the polishing surface of the polishing pad, and contacting the surface of the semiconductor structure with the polishing surface of the polishing pad to polish the surface with the polishing slurry. A method of manufacturing a semiconductor device including the the chemical mechanical polishing method, a polishing pad used in the method, and a chemical mechanical polishing device.

This application claims priority to Korean Patent Application No. 10-2019-0104348 filed in the Korean Intellectual Property Office on Aug. 26, 2019, and all benefits accruing therefrom under 35 U.S.C. § 119, the entire content of which is herein incorporated by reference.

### BACKGROUND

### 1. Field

A chemical mechanical polishing method, a method of manufacturing a semiconductor device, a polishing pad, and a chemical mechanical polishing device are disclosed.

### 2. Description of the Related Art

A semiconductor device is required to have a structure with a planar surface during the manufacturing process, and the structure may be obtained by a polishing process. One example of the polishing process may be a chemical mechanical polishing (CMP). Chemical mechanical polishing is a process including providing polishing slurry including abrasives between a substrate or structure to be polished and a polishing pad and contacting a surface of the substrate or structure with the polishing pad to planarize a surface of the substrate, e.g., to planarize a surface of a semiconductor structure.

A high-performance and highly-integrated semiconductor device is often required to have a structure with a fine pitch of less than or equal to about 10 nm. However, common polishing slurries including abrasives of tens of nanometers in particle diameter such as silica abrasive may cause damage and deformation of the fine pitch structure.

### SUMMARY

An embodiment provides a chemical mechanical polishing method capable of improving a polishing rate and reducing damage and shape deformations of a structure, e.g., a fine surface structure of a semiconductor device.

Another embodiment provides a method of manufacturing a semiconductor device using the chemical mechanical polishing method.

Another embodiment provides a polishing pad for use in the chemical mechanical polishing method.

Another embodiment provides a chemical mechanical polishing device for use in the chemical mechanical polishing method.

According to an embodiment, a chemical mechanical polishing method includes preparing a polishing pad including a polishing surface having an elastic modulus of about 300 megapascals (MPa) to about 400 MPa at room temperature, positioning a semiconductor structure having a surface, wherein the structure surface and the polishing surface of the polishing pad face each other, supplying polishing slurry including nano-abrasive having an average particle diameter of less than about 10 nanometers (nm) between the surface of the semiconductor structure and the polishing surface of the polishing pad, and contacting the surface of the semiconductor structure with the polishing surface of the polishing pad to polish the surface of the semiconductor structure.

The polishing surface of the polishing pad may have an elastic modulus of about 340 MPa to about 360 MPa at room temperature.

The polishing surface of the polishing pad may have an average pore size of about 20 micrometers (μm) to about 40 μm and a pore density of about 50 percent (%) to about 60%.

The polishing surface of the polishing pad may have a hardness of about 50 Shore D to about 55 Shore D.

An average particle diameter of the nano-abrasives may be greater than or equal to about 0.1 nm and less than about 5 nm.

The nano-abrasives may include carbon polishing particles.

The carbon polishing particles may include fullerene or a fullerene derivative, graphene, graphite, carbon nanotube, carbon dot, or a combination thereof.

The carbon polishing particles may include hydrophilic fullerene having at least one hydrophilic functional group, and the hydrophilic functional group may include at least one of a hydroxyl group, an amino group, a carbonyl group, a carboxyl group, a sulfhydryl group, and a phosphate group.

The carbon polishing particles may include hydroxyl fullerene represented by Cₓ(OH)_{y} (wherein x is 60, 70, 74, 76, or 78, and y is an integer from 12 to 44).

In the polishing of the surface of the semiconductor surface, a temperature of the polishing pad is maintained at a temperature, which may not substantially change.

According to another embodiment, a method of manufacturing a semiconductor device including the chemical mechanical polishing method is provided.

The chemical mechanical polishing method may be applied to polishing a metal layer of a semiconductor structure.

According to another embodiment, a polishing pad including a polishing surface having an elastic modulus of about 300 MPa to about 400 MPa at room temperature is provided.

The polishing pad in combination with the polishing slurry including nano-abrasive having an average particle diameter of less than about 10 nm may be used in the described chemical mechanical polishing method.

In the instance the surface of the semiconductor structure includes a metal layer, a polishing rate of the metal layer using the polishing pad may increase as the elastic modulus of the polishing surface decreases.

The polishing surface may have an elastic modulus of about 340 MPa to about 360 MPa at room temperature.

The polishing surface may have a plurality of pores, an average pore size of the plurality of pores being about 20 μm to about 40 μm and a pore density of the plurality of pores being about 50% to about 55%.

The polishing surface may have a hardness of about 50 Shore D to about 55 Shore D.

The polishing pad may include a first layer including the polishing surface and a second layer having an elastic modulus greater than the elastic modulus of the first layer.

According to another embodiment, a chemical mechanical polishing device includes a rotatable platen, the polishing pad disposed on the platen, and a polishing slurry supplier for supplying polishing slurry to the polishing pad disposed adjacent to the polishing pad.

In accordance with the chemical mechanical polishing method, the polishing rate may be improved, and damage or shape deformation of the structure may be minimized.

### BRIEF DESCRIPTION OF THE DRAWINGS

FIG. 1 is a schematic view showing a chemical mechanical polishing device according to an embodiment,

FIG. 2 represents an insulation layer on a substrate with trenches formed in the insulation layer, and a conductive layer formed on the walls and floor of the trenches;

FIG. 3 represents a metal layer of an embodiment formed on the conductive layer and fills the trenches of FIG. 2;

FIG. 4 represents a metal structure of an embodiment that is planarized to coincide with a surface of the insulation layer; and

FIG. 5 represents a metal structure of an embodiment with a capping layer.

### DETAILED DESCRIPTION

Example embodiments will hereinafter be described in detail and may be easily performed by a person having an ordinary skill in the related art. However, this disclosure may be embodied in many different forms and is not to be construed as limited to the example embodiments set forth herein. Rather, these embodiments are provided so that this disclosure will be thorough and complete, and will fully convey the scope of the invention to those skilled in the art. In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various compounds, components, regions, layers and/or sections, these compounds, components, regions, layers and/or sections should not be limited by these terms. These terms are only used to distinguish one compound, component, region, layer or section from another compound, component, region, layer, or section.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a chemical mechanical polishing device according to an embodiment is described.

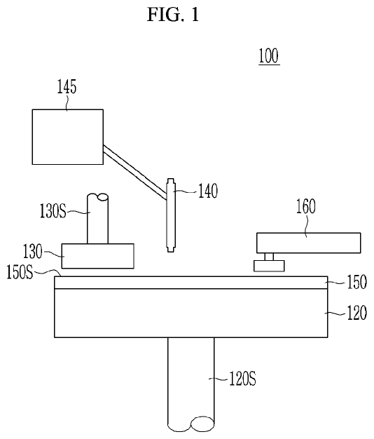

FIG. 1 is a schematic view showing a chemical mechanical polishing device according to an embodiment.

Referring to FIG. 1, a chemical mechanical polishing device 100 includes a platen 120; a polishing head 130; a polishing slurry supplier 140; a polishing pad 150; and a pad conditioner 160.

The platen 120 may be provided to be rotatable on the surface of the lower base (not shown). The platen 120 may receive a rotational power from a motor (not shown) disposed in the lower base, and thus may rotate in a predetermined direction such as a clockwise direction or a counterclockwise direction by a rotation axis 120S perpendicular to the surface of the platen 120.

The polishing head 130 may be disposed on the upper surface of the platen 120 and may hold a polished object. The polished object may be a semiconductor structure such as for example a wafer. The polishing head 130 may include a rotation axis 130S that rotates the polished object. When the polishing is performed, the rotation direction of the polishing head 130 may be opposite to the rotation direction of the platen 120.

The polishing slurry supplier 140 may be supplied with polishing slurry from the polishing slurry tank 145 and discharge the polishing slurry on the polishing pad 150 that will be described later. The polishing slurry supplier 140 may include a nozzle supplying the polishing slurry on the polishing pad 150 during the polishing process and may include a voltage-applying unit to apply a predetermined voltage to the nozzle. The voltage applied from the voltage-applying unit may charge the polishing slurry in the nozzle and discharge the polishing slurry toward and onto the polishing pad 150. The polishing slurry may include nano-abrasive having an average particle diameter of less than about 10 nm, which will be described later.

The polishing pad 150 may be disposed on the upper surface of the platen 120 and thus supported by the platen 120. The polishing pad 150 may be rotated with the platen 120.

The polishing pad 150 may have a polishing surface 150S disposed to face the polished object held by the polishing head 130, that is, a semiconductor structure such as a wafer. When the polishing is performed, the polishing surface 150S of the polishing pad 150 may directly contact the polished object and thus chemical and/or mechanically polish the surface of the polished object by using the nano-abrasives in the polishing slurry. Herein, the polishing surface 150S of the polishing pad 150 may have the surface directly contacting the polished object and a predetermined depth therefrom, and the predetermined depth may be about 10% to about 100%, about 20% to about 100%, about 30% to about 100%, about 40% to about 100% or about 50% to about 100% of a thickness of the polishing pad 150.

The polishing surface 150S of the polishing pad 150 may have a relatively low elastic modulus at room temperature (a room temperature elastic modulus), so that it may be elastically deformed, when it contacts the nano-abrasives in the polishing slurry. Herein, the elastic modulus at room temperature may exhibit a degree of resistance against deformation of a material at room temperature (e.g., 25° C.). For example, a polishing surface with a low elastic modulus at room temperature means that the material has small resistance against deformation at room temperature and thus may be easily deformed. In contrast, a polishing surface with a relatively high elastic modulus at room temperature means that the material has large resistance against deformation at room temperature and thus may not be easily deformed. The elastic modulus at room temperature may be for example a Young's modulus at room temperature (about 25° C.), and is determined by using a dynamic mechanical analyzer (RSA-G2 Solid Analyzer, TA Instruments).

In this way, the polishing pad 150 includes the polishing surface 150S having a relatively low elastic modulus at room temperature and accordingly, may easily deform the polishing surface 150S by the nano-abrasive during the polishing. As a result, the contact area between the polishing surface 150S of the polishing pad 150 and the nano-abrasive, or between the polishing surface 150S of the polishing pad 150 and the polished object, increases and thus improve polishing performance.

For example, the polishing surface 150S of the polishing pad 150 may have an elastic modulus of about 300 MPa to about 400 MPa at room temperature. The polishing surface 150S of the polishing pad 150 has an elastic modulus within the range and thus may effectively suppress generation of debris during the polishing of using the nano-abrasive, and sufficiently maintain the contact areas between the polishing surface 150S of the polishing pad 150 and the nano-abrasive, or between the polishing surface 150S of the polishing pad 150 and the polished object. Within the range, the polishing surface 150S of the polishing pad 150 may have an elastic modulus of about 300 MPa to about 380 MPa, about 300 MPa to about 360 MPa, about 320 MPa to about 380 MPa, about 320 MPa to about 360 MPa, about 340 MPa to about 380 MPa, or about 340 MPa to about 360 MPa, at room temperature.

The polishing pad 150 may be a porous pad having a plurality of fine pores, and the plurality of fine pores may hold the polishing slurry. For example, the polishing surface 150S of the polishing pad 150 may have a pore size (average pore size (diameter)) of less than or equal to about 50 micrometers (μm), within the range, about 10 μm to about 50 μm, about 20 μm to about 40 μm, about 25 μm to about 38 μm, about 28 μm to about 35 μm, about 29 μm to about 33 μm, or about 29 μm to about 31 μm. For example, the polishing surface 150S of the polishing pad 150 may have a pore density of about 40% to about 60%, within the range, about 45% to about 60%, about 50% to about 60%, about 53% to about 58%, or about 54% to about 56%. The average pore size and the pore density may be determined by using a magnified image obtained from a scanning electron microscope (SEM).

The polishing surface 150S of the polishing pad 150 may have a hardness of about 50 shore D to about 60 shore D, within the range, about 51 shore D to about 58 shore D, about 51 shore D to about 55 shore D.

The polishing surface 150S of the polishing pad 150 may be for example, flat. The polishing surface 150S of the polishing pad 150 may have for example, protrusions or grooves.

For example, the polishing pad 150 may include a plurality of layers having different properties.

For example, the polishing pad 150 may include a first layer including the polishing surface 150S having the aforementioned properties of average pore size and pore density, and a second layer having different properties from the first layer. The first layer of the polishing pad 150 may be disposed to face the polishing head 130, and the second layer of the polishing pad 150 may be disposed to face the platen 120.

For example, the polishing pad 150 may include a first layer having an elastic modulus of about 300 megapascals (MPa) to about 400 MPa at room temperature and a second layer having an elastic modulus greater than that of the first layer. The elastic modulus of the second layer at room temperature may be for example, in a range of greater than about 400 MPa to about 1000 MPa and within the range, about 450 MPa to about 800 MPa.

For example, an average pore size of the first layer of the polishing pad 150 may be the same as described above, and an average pore size of the second layer of the polishing pad 150 may be greater than or less than that of the first layer.

For example, pore density of the first layer of the polishing pad 150 may be the same as described above, and pore density of the second layer of the polishing pad 150 may be greater than or less than that of the first layer.

For example, hardness of the first layer of the polishing pad 150 may be the same as described above, and hardness of the second layer of the polishing pad 150 may be greater than or less than that of the first layer.

The pad conditioner 160 may be disposed adjacent to the polishing pad 150 and maintain a near constant surface roughness of the polishing surface 150S of the polishing pad 150 so that the polished object may be effectively polished during the polishing process. For example, the pad conditioner 160 may recover or maintain the surface roughness of the polishing surface 150S of the polishing pad 150 by polishing the polishing surface 150S of the polishing pad 150 during polishing of the object or at a time when polishing of the object is halted. The pad conditioner 160 may be rotated in a predetermined direction such as a clockwise direction or a counterclockwise direction along with a rotation axis.

The chemical mechanical polishing device 100 may further include a surface roughness measuring device (not shown) to measure the surface roughness of the polishing surface 150S of the polishing pad 150. The surface roughness measuring device measures the surface roughness of the polishing surface 150S of the polishing pad 150 in real time, and thus, achieve constant polishing performance.

Hereinafter, a chemical mechanical polishing method according to an embodiment is described.

A chemical mechanical polishing method according to an embodiment includes preparing the aforementioned chemical mechanical polishing device 100, disposing the polishing surface 150S of the polishing pad 150 and the polished object such as a semiconductor substrate to face each other, supplying a polishing slurry between the polished object such as the semiconductor substrate and the polishing surface 150S of the polishing pad 150, and contacting the polished object such as the semiconductor substrate with the polishing surface 150S of the polishing pad 150 to polish the polished object such as the semiconductor substrate. The term “preparing” refers to and includes a single commercial entity actually making or assembling the article stated and performing the actual steps of the chemical mechanical polishing method, or having a another party make or assemble the article stated and then providing the article to another person or commercial entity that actually performs the described chemical mechanical polishing method. As described above, the chemical mechanical polishing device 100 may include a polishing pad 150 having a polishing surface 150S having predetermined properties.

For example, the polishing surface 150S of the polishing pad 150 may have a relatively low elastic modulus at room temperature of about 300 MPa to about 400 MPa, within the range, an elastic modulus at room temperature of about 300 MPa to about 380 MPa, about 300 MPa to about 360 MPa, about 320 MPa to about 380 MPa, about 320 MPa to about 360 MPa, about 340 MPa to about 380 MPa, or about 340 MPa to about 360 MPa.

For example, the polishing surface 150S of the polishing pad 150 may have an average pore size (diameter) of less than or equal to about 50 micrometers (μm), within the range, about 10 μm to about 50 μm, about 20 μm to about 40 μm, about 25 μm to about 38 μm, about 28 μm to about 35 μm, about 29 μm to about 33 μm, or about 29 μm to about 31 μm.

For example, the polishing pad 150 may have a pore density of about 40% to about 60%, within the range, about 45% to about 60%, about 50% to about 60%, about 53% to about 58%, or about 54% to about 56%.

For example, the polishing surface 150S of the polishing pad 150 may have a hardness of about 50 shore D to about 60 shore D, within the range, about 51 shore D to about 58 shore D, about 51 shore D to about 55 shore D.

For example, the polishing pad 150 may have a pore density of about 50% to about 60%, or about 53% to about 58%, and a hardness of 51 shore D to about 58 shore D, or about 51 shore D to about 55 shore D.

The polishing pad 150 may include a polymer and may include for example polyurethane. The polyurethane may be obtained by mixing a polyurethane precursor with a hardener. The polyurethane precursor may be obtained, for example, by a reaction of an isocyanate compound and a polyol compound.

The isocyanate compound may be for example aliphatic isocyanate and/or aromatic isocyanate, for example diisocyanate. It may be, for example ethylene diisocyanate, hexamethylene diisocyanate, bis(isocyanatomethyl)cyclohexane, norbornane diisocyanate, isophorone diisocyanate, dicyclohexylmethane diisocyanate, toluene diisocyanate, naphthalene diisocyanate, phenylene diisocyanate, tolidine diisocyanate, 2,2′-diphenylmethane diisocyanate, 2,4′-diphenylmethane diisocyanate, 4,4′-diphenylmethane diisocyanate, xylene diisocyanate, or a combination thereof, but is not limited thereto.

The polyol compound may be for example polyether polyol, polyester polyol, polycarbonate polyol, polyester polycarbonate polyol, acryl polyol, or a combination thereof, but is not limited thereto.

The polyurethane precursor may be formed from a polyurethane precursor composition. The polyurethane precursor composition may be a photocurable polyurethane precursor composition or a thermocurable polyurethane precursor composition.

The photocurable polyurethane precursor composition may include a photocurable polyurethane precursor and the photocurable polyurethane precursor may include, for example, urethane (meth)acrylate. The urethane (meth) acrylate may be obtained by further reaction with a (meth)acrylate compound after a polymerization reaction of the isocyanate compound and the polyol compound.

The (meth)acrylate compound may be, for example, 2-hydroxyethyl-(meth)acrylate, 2-hydroxypropyl(meth)acrylate, 4-hydroxybutyl(meth)acrylate, pentaerythritol tri(meth)acrylate, or a combination thereof, but is not limited thereto.

The urethane (meth) acrylate may have a structure having one or two (meth)acrylate groups (CH₂═CHC(═O)O—, or CH₂═CCH₃C(═O)O—) at the terminal end of the core having an urethane moiety. The (meth) acrylate group at the terminal end may be a functional group capable of crosslinking, and may be referred to as a chemical crosslinking site.

The polyurethane precursor composition may further include a reaction initiator. The reaction initiator may be, for example, benzophenone, methylbenzophenone, xylol benzophenone, acetophenone, benzyldimethylketal, diethylthioxanthone, diphenyl(2,4,6-trimethylbenzoyl) phosphine oxide, anthraquinone, or a combination thereof, but is not limited thereto.

The polyurethane precursor composition may optionally further include an organic solvent. The organic solvent may include, for example, a ketone solvent such as acetone, methylethylketone, methylisobutylketone, and the like; a cyclic ether solvent such as tetrahydrofuran, dioxolane, and the like; an ester solvent such as methyl acetate, ethyl acetate, butyl acetate, and the like; an aromatic solvent such as toluene, xylene, and the like; an alicyclic solvent such as cyclohexane, methyl cyclohexane, and the like; an alcohol solvent such as carbitol, cellosolve, methanol, isopropanol, butanol, propylene glycol monomethylether, and the like; a glycol ether solvent such as ethylene glycol monoethylether, ethylene glycol monobutylether, propylene glycol monomethylether, propylene glycol monopropylene ether, and the like; or a combination thereof, but is not limited thereto.

The polyurethane precursor may be mixed with the hardener, and inert gas may be supplied to obtain porous polyurethane.

The hardener may be for example an aliphatic amine compound, an aromatic amine compound, an aliphatic alcohol compound, an aromatic alcohol compound, or a combination thereof, but is not limited thereto.

The inert gas may be for example nitrogen gas, argon gas, helium, and mixed gases thereof, but is not limited thereto. The inert gas may be supplied evenly to the mixture of polyurethane and hardener. For example, the size and density of the pores of the porous polyurethane may be controlled by adjusting the type, supply flow rate, and/or supply pressure of the inert gas.

The mixture of the polyurethane precursor and hardener may be injected into a predetermined mold and reacted to obtain polyurethane. The weight average molecular weight of the obtained polyurethane may be about 500 grams per mole (g/mol) to about 20,000 g/mol or about 500 g/mol to about 10,000 g/mol. The polyurethane may be molded into a solid-phase in the shape of a mold and may be obtained as a shaped body in a form of a cake. The shaped body may be sliced or cut to a predetermined thickness to obtain a polishing pad 150 in a form of a sheet.

The polishing slurry may be discharged onto the polishing pad 150 from the aforementioned polishing slurry supplier 140.

The polishing slurry may include nano-abrasives having an average particle diameter of less than about 10 nm. The nano-abrasive may have for example an average particle diameter of greater than or equal to about 0.1 nm and less than about 10 nm, for example greater than or equal to about 0.1 nm and less than about 8 nm, greater than or equal to about 0.1 nm and less than about 7 nm, greater than or equal to about 0.1 nm and less than about 5 nm. By using nano-abrasive having a relatively small average particle diameter within the ranges, the polishing slurry may be effectively applied to polish fine pitch structures having a width of less than about 10 nm, and damages to such structures, e.g., scratching and dishing, may be effectively prevented, minimized, or reduced.

The nano-abrasive may include for example carbon nano-abrasive. The carbon nano-abrasives may be made of carbon or include carbon as a primary elemental component, and may be a two-dimensional or three-dimensional nanoparticle made of carbon or including carbon as a primary elemental component. The carbon nano-abrasive may be superior to chemical polishing rather than mechanical polishing, that is, unlike large oxide abrasives with tens of nanometer diameters such as silica or alumina.

For example, the carbon nano-abrasive may include fullerene or a to fullerene derivative, graphene, graphite, carbon nanotube, carbon dot or a combination thereof.

For example, the carbon nano-abrasive may be fullerene or a fullerene derivative. The fullerene may be, for example, C60, C70, C74, C76, or C78, but is not limited thereto.

For example, the fullerene derivative may be a hydrophilic fullerene, and the hydrophilic fullerene may be a structure in which at least one hydrophilic functional group is bound to the fullerene core. The fullerene core may be, for example, C60, C70, C74, C76, or C78, but is not limited thereto. The hydrophilic functional group may be for example at least one of a hydroxyl group, an amino group, a carbonyl group, a carboxyl group, a sulfhydryl group, and a phosphate group, but is not limited thereto. The hydrophilic functional group may be for example a hydroxyl group.

The hydrophilic fullerene may include at least 2 hydrophilic functional groups in average, for example 2 to 44 hydrophilic functional groups in average, 8 to 44 hydrophilic functional groups in average, 12 to 44 hydrophilic functional groups in average, 24 to 44 hydrophilic functional groups in average, 24 to 40 hydrophilic functional groups in average, 24 to 38 hydrophilic functional groups in average, 32 to 44 hydrophilic functional groups in average, 32 to 40 hydrophilic functional groups in average, or 32 to 38 hydrophilic functional groups in average per the fullerene core.

For example, the hydrophilic fullerene may be hydroxyl fullerene, and may be for example represented by Cₓ(OH)_{y} (wherein, x may be 60, 70, 74, 76, or 78 and y may be an integer from 2 to 44). Wherein the average number of hydroxy groups in the hydroxyl fullerene may be measured by an atomic analysis, a thermogravimetric analysis, a spectrophotometric analysis, a mass analysis, and the like, for example, it may be an average of two highest peaks in the liquid chromatography mass spectrum (LCMS).

For example, the hydrophilic fullerene may be hydroxyl fullerene represented by Cₓ(OH)_{y} (wherein x may be 60, 70, 74, 76, or 78, and y may be an integer from 12 to 44).

For example, the hydrophilic fullerene may be hydroxyl fullerene represented by Cₓ(OH)_{y} (wherein x may be 60, 70, 74, 76, or 78, and y may be an integer from 24 to 44).

For example, the hydrophilic fullerene may be hydroxyl fullerene represented by Cₓ(OH)_{y} (wherein x may be 60, 70, 74, 76, or 78, and y may be an integer from 32 to 44).

The hydrophilic fullerene may be effectively dispersed in water.

The carbon nano-abrasive may be included in an amount of about 0.001 weight percent (wt %) to about 5 wt % in the polishing slurry. Within the range, the carbon nano-abrasive may be included in an amount of about 0.001 wt % to about 3 wt %, about 0.001 wt % to about 2 wt %, about 0.001 wt % to about 1 wt %, about 0.001 wt % to about 0.8 wt %, or about 0.001 wt % to about 0.5 wt %, in the polishing slurry.

As for the nano-abrasive such as carbon nano-abrasive, chemical polishing may be superior to mechanical polishing, and unlike large oxide abrasives having tens of nanometer diameters such as silica or alumina. As for the nano-abrasive having a very small size and adopting the chemical polishing as superior polishing, and unlike the large oxide abrasive, it may be important to increase contact areas among a polishing pad, a polished object and the nano-abrasive in order to promote a chemical reaction. As described above, the polishing pad including the polishing surface having a relatively low elastic modulus may be used to effectively increase the contact areas among the polishing pad, the polished object and nano-abrasive during the polishing and thus improve a polishing rate.

The polishing slurry may further include an additive and the additive may be for example a chelating agent, an oxidizing agent, a surfactant, a dispersing agent, a pH controlling agent, or a combination thereof, but is not limited thereto.

The chelating agent may be for example phosphoric acid, nitric acid, citric acid, malonic acid, a salt thereof, or a combination thereof, but is not limited thereto.

The oxidizing agent may be for example hydrogen peroxide, hydrogen peroxide water, sodium hydroxide, potassium hydroxide, or a combination thereof, but is not limited thereto.

The surfactant may be an ionic or non-ionic surfactant, for example a copolymer of ethylene oxide, a copolymer of propylene oxide, an amine compound, or a combination thereof, but is not limited thereto.

The dispersing agent promotes uniform dispersion of the nano-abrasive and may include, for example a water-soluble monomer, a water-soluble oligomer, a water-soluble polymer, a metal salt, or a combination thereof. The water-soluble polymer may have a weight average molecular weight of, for example, less than or equal to about 10,000 g/mol, less than or equal to about 5000 g/mol, or less than or equal to about 3000 g/mol. The metal salt may be for example a copper salt, a nickel salt, a cobalt salt, a manganese salt, a tantalum salt, a ruthenium salt, or a combination thereof. The dispersing agent may be for example poly(meth)acrylic acid, poly(meth)acryl maleic acid, polyacrylonitrile-co-butadiene-acrylic acid, carboxylic acid, sulfonic ester, sulfonic acid, phosphoric ester, cellulose, diol, a salt thereof, or a combination thereof, but is not limited thereto.

The pH controlling agent may control pH of the polishing slurry and may be for example inorganic acid, organic acid, a salt thereof, or a combination thereof. The inorganic acid may include for example nitric acid, hydrochloric acid, phosphoric acid, sulfuric acid, hydrofluoric acid, bromic acid, iodic acid or a salt thereof, the organic acid may include for example formic acid, malonic acid, maleic acid, oxalic acid, adipic acid, citric acid, acetic acid, propionic acid, fumaric acid, lactic acid, salicylic acid, benzoic acid, succinic acid, phthalic acid, butyric acid, glutaric acid, glutamic acid, glycolic acid, lactic acid, aspartic acid, tartaric acid, or a salt thereof, but is not limited thereto.

Each additive may be independently for example included in a trace amount of about 1 part per million (ppm) to 100,000 ppm, but is not limited thereto.

The polishing slurry may further include a solvent capable of dissolving or dispersing the aforementioned polishing slurry components and the solvent may be for example water. The water may be for example distilled water and/or deionized water.

For example, the polishing slurry may be supplied from the polishing slurry supplier 140 at about 10 milliliters per minute (ml/min) to about 100 ml/min, for example, at a flow rate of about 2 microliters (μl) to about 10 (μl).

The polishing may be performed by contacting a polished object such as a surface of a semiconductor structure with the polishing surface 150S of the polishing pad 150 and then, rotating one or both of the object (structure) or the pad 150. A rotation direction of the polished object may be opposite to a rotation direction of the platen 120, but is not limited thereto.

While the polishing is performed, a predetermined pressure may be applied thereto, for example, about 1 pounds per square inch (psi) to about 100 psi, about 2 psi to about 100 psi, about 1 psi to about 90 psi, about 2 psi to about 90 psi, about 10 psi to about 90 psi, about 30 psi to about 90 psi, or about 50 psi to about 90 psi. For example, when a relatively high pressure of about 30 psi to about 90 psi or about 50 psi to about 90 psi is applied during the polishing, the contact area of the polished object and the polishing surface 150S of the polishing pad 150 may be further increased, and the polishing rate may be further improved.

When the polishing is performed by using the polishing slurry including nano-abrasive such as carbon nano-abrasive, and unlike large oxide abrasives having tens of nanometer diameter such as silica or alumina, friction heat generated during the polishing is almost absent, and thus a temperature of the polishing pad 150 may not substantially change during the polishing. Accordingly, a possible change in elastic modulus at a temperature of greater than or equal to about 30° C. of the polishing surface 150S of the polishing pad 150 need not be of concern or considered.

In addition, since the temperature of the polishing pad 150 is not substantially increased during the polishing, i.e., there is no substantial change in temperature at the pad surface during polishing, separate cooling may not be necessary, unlike the use of large oxide abrasive having tens of nanometer diameters such as silica or alumina. For example, the term “no substantial change” in reference to temperature may refer to a temperature change of plus-minus 30%. For example, if the polishing of the object is to be conducted at or near room temperature (23° C.), then the temperature may vary from 16° C. to 30° C.

The aforementioned chemical mechanical polishing method may be applied to form various structures, for example, effectively applied to a polishing process of a conductor such as a metal wire and/or an insulator such as an oxide, a nitride, or an oxynitride. For example, the aforementioned chemical mechanical polishing method may be used to polish a conductor such as a metal wire in a semiconductor substrate and may be used to polish a conductor such as copper (Cu), tungsten (W), or an alloy thereof.

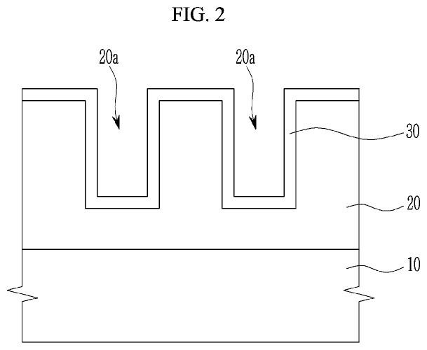

FIGS. 2 to 5 are cross-sectional views showing a method of manufacturing a semiconductor device according to an embodiment.

Referring to FIG. 2, an interlayer insulating layer 20 is formed on a semiconductor substrate 10. The interlayer insulating layer 20 may include an oxide, a nitride, and/or an oxynitride. Subsequently, the interlayer insulating layer 20 is etched to provide a trench 20a. The trench 20a may have a width of less than or equal to about 20 nm, less than or equal to about 15 nm, or less than or equal to about 10 nm. Subsequently, a barrier layer 30 is formed on the wall surface of the trench. The barrier layer 30 may include, for example, Ta and/or TaN, but is not limited thereto.

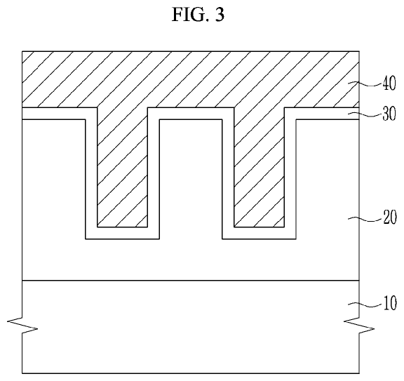

Referring to FIG. 3, a metal such as copper (Cu) or tungsten (W) fills the inside of the trench to provide a metal layer 40.

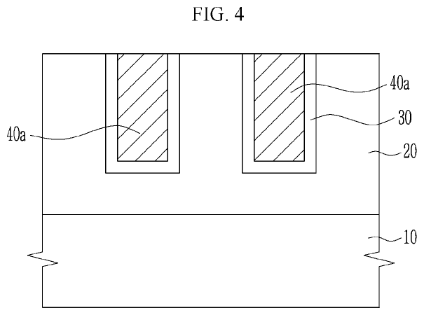

Referring to FIG. 4, a surface of the metal layer 40 is planarized to coincide with the surface of the interlayer insulating layer 20 to form a filled metal layer 40a. The planarization may be performed by chemical mechanical polishing using the aforementioned chemical mechanical polishing device according to the chemical mechanical polishing method as described above. For example, when the barrier layer 30 is a Ta layer and the metal layer 40 is a Cu layer, the polishing selectivity of Ta to Cu is improved or increased with the aforementioned polishing slurry, for example, the polishing selectivity of Ta to Cu is greater than about 50:1.

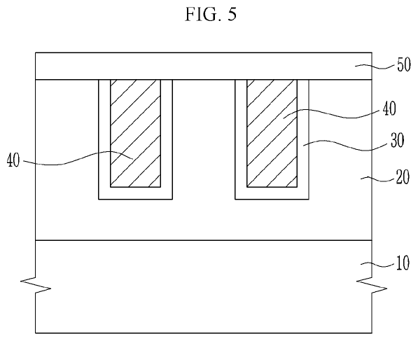

Referring to FIG. 5, a capping layer 50 is formed on the filled and planarized metal layer 40a and the interlayer insulating layer 20. The capping layer 50 may include SiN and/or SiC, but is not limited thereto. The capping layer 50 may be unnecessary, and therefore, omitted.

The method of manufacturing a semiconductor device according to some examples has been described above, but the present disclosure is not limited thereto and may be applied to semiconductor devices having various structures. Hereinafter, the embodiments are illustrated in more detail with reference to examples. However, these examples are exemplary, and the present disclosure is not limited thereto.

### SYNTHESIS EXAMPLE

### Synthesis of Nano Abrasive

A bead mill vessel having a height of about 100 millimeters (mm) and a diameter of about 50 mm is filled with beads to about 1/3 volume, and then, 1 gram (g) of fullerene (C60, Nanom purple ST, Frontier Carbon Corp.), 0.5 grams per Liter (g/L) of a dispersing agent (polyacrylic acid, Mw 1800, Merck & Co., Inc.), and 100 g of water are added to the mill. The beads are a mixture of 50 g of zirconia beads having an average particle diameter of 500 micrometers (pm), 50 g of zirconia beads having an average particle diameter of 5 mm, and 50 g of zirconia beads having an average particle diameter of 10 mm.

Subsequently, after rotating the vessel for 40 hours, a sample of fullerene particles is removed from the mill, and the sample measured for average particle diameter. The particle diameter is measured by using a dynamic light scattering-type Zeta-potential & particle size analyzer, ELS-Z (Otsuka Electronics Co., Ltd.). The mill is rotated until a sample of milled fullerene particles have an average particle diameter of less than or equal to 100 nm. After the desired particle size is achieved the beads are removed from the mill, and 100 g of a 30 wt % hydrogen peroxide water is added to the fullerene particle mixture. The fullerene particle mixture is then stirred at about 70° C. for 8 days to prepare hydroxyl fullerene dispersion.

A particle diameter of the hydroxyl fullerene is measured by using the dynamic light scattering-type Zeta-potential & particle size analyzer (ELS-Z).

The average number of a hydroxy group of the hydroxyl fullerene is evaluated by calculating an average of two highest peaks in a mass spectrum of the hydroxyl fullerene in a Fourier transform infrared spectroscopy (FTIR) method. The resulting hydroxyl fullerene (or fullerene derivative) is confirmed and best represented as C₆₀(OH)₃₄ having an average particle diameter of 2.5 nm and an average hydroxy group of 34.

### Preparation Example I

### Preparation of Polishing Slurry

### Preparation Example 1

An aqueous mixture (polishing slurry) is prepared including 0.02 wt % of hydroxyl fullerene represented by C₆₀(OH)₃₄ according to Synthesis Example, 0.1 wt % of glycine, 0.1 wt % of malonic acid, and 0.01 wt % of ferric nitrate in water.

### Preparation Example 2

An aqueous mixture (polishing slurry) is prepared including 0.1 wt % of hydroxyl fullerene represented by C₆₀(OH)₃₄ according to Synthesis Example, 0.1 wt % of glycine, 0.1 wt % of malonic acid, and 0.01 wt % of ferric nitrate in water.

### Comparative Preparation Example 1

A polishing slurry is prepared according to Preparation Example 1 except that silica (with an average particle diameter: 40 nm, Fujimi Corp.) is added instead of the hydroxyl fullerene.

### Preparation Example II

### Manufacture of Polishing Pad

### Preparation Examples A to C

Polishing pads having properties shown in Table 1 are manufactured by preparing a mixture of water and polyurethane, providing N₂ or air, treated though a casting process, and adding an acid to form pores inside the polyurethane and to adjust density of the pores.

### Comparative Preparation Example A

A commercially available polishing pad (IC1000™, Dow Chemical Company) is represented as Comparative Preparation Example A.

TABLE 1

| | Elastic | Average | Pore | |
|---|---|---|---|---|
| | modulus | Pore Size | Density | |
| | (MPa, @25° C.) | (μm) | (%) | Hardness |
| Preparation | 340 | 30 ± 1 | 54-56 | 51-55 |
| Example A | | | | |
| Preparation | 350 | 30 ± 1 | 54-56 | 51-55 |
| Example B | | | | |
| Preparation | 360 | 30 ± 1 | 54-56 | 51-55 |
| Example C | | | | |
| Comparative | 518 | — | — | — |
| Preparation | | | | |
| Example A | | | | |

* Elastic modulus: measured by RSA-G2 Solid Analyzer (TA Instrument) (Auto-tension Auto-strain setting)
* Average Pore Size/Pore Density: confirmed from magnified image of scanning electron microscope (SEM)
* Hardness: Shore D (using a D-type hardness meter)

### EXAMPLES

### Example 1

Chemical mechanical polishing is performed under the following conditions

(1) CMP equipment: MA-200e (Musashino Electronic Corp.)

(2) Polished object (wafer): a 12 inch-thick silicon wafer having a 600 nm-thick tungsten (W) film thereon

(3) Polishing pad: the polishing pad according to Preparation Example A

(4) Rotation number of a polishing head: 87 revolutions per minute (rpm)

(5) Rotation number of polishing platen: 93 rpm

(6) Applied pressure: 2 to 3 psi

(7) Polishing temperature: room temperature (25° C.)

(8) Polishing slurry: polishing slurry according to Preparation Example 1

(9) Method of supplying polishing slurry: 100 milliliters (ml) of polishing slurry is put on the polishing pad and polishing is performed.

### Example 2

Chemical mechanical polishing is performed according to the same method as Example 1 except that the polishing pad of Preparation Example B is used instead of the polishing pad of Preparation Example A.

### Example 3

Chemical mechanical polishing is performed according to the same method as Example 1 except that the polishing pad of Preparation Example C is used instead of the polishing pad of Preparation Example A.

### Example 4

Chemical mechanical polishing is performed according to the same method as Example 1 except that the polishing slurry of Preparation Example 2 is used instead of the polishing slurry of Preparation Example 1.

### Example 5

Chemical mechanical polishing is performed according to the same method as Example 1 except that the polishing pad of Preparation Example B is used instead of the polishing pad of Preparation Example A and the polishing slurry of Preparation Example 2 is used instead of the polishing slurry of Preparation Example 1.

### Example 6

Chemical mechanical polishing is performed according to the same method as Example 1 except that the polishing pad of Preparation Example C is used instead of the polishing pad of Preparation Example A and the polishing slurry of Preparation Example 2 is used instead of the polishing slurry of Preparation Example 1.

### Comparative Example 1

Chemical mechanical polishing is performed according to the same method as Example 1 except that the polishing pad of Comparative Preparation Example A is used instead of the polishing pad of Preparation Example A.

### Comparative Example 2

Chemical mechanical polishing is performed according to the same method as Example 1 except that the polishing pad of Comparative Preparation Example A is used instead of the polishing pad of Preparation Example A and the polishing slurry of Preparation Example 2 is used instead of the polishing slurry of Preparation Example 1.

### Comparative Example 3

Chemical mechanical polishing is performed according to the same method as Example 1 except that the polishing pad of Comparative Preparation Example 1 is used instead of the polishing pad of Preparation Example 1.

### Comparative Example 4

Chemical mechanical polishing is performed according to the same method as Example 1 except that the polishing pad of Preparation Example B is used instead of the polishing pad of Preparation Example A and the polishing slurry of Comparative Preparation Example 1 is used instead of the polishing slurry of Preparation Example 1.

### Comparative Example 5

Chemical mechanical polishing is performed according to the same method as Example 1 except that the polishing pad of Preparation Example C is used instead of the polishing pad of Preparation Example A and the polishing slurry of Comparative Preparation Example 1 is used instead of the polishing slurry of Preparation Example 1.

### Evaluation

Each polishing rate (material removal rate, MRR) is evaluated after the chemical mechanical polishing according to Examples and Comparative Examples.

The polishing rate is calculated by performing polishing for 60 seconds, converting sheet resistance into a thickness of a tungsten film before and after the polishing, and obtaining a rate therefrom.

The results are shown in Table 2.

TABLE 2

| | Preparation | Preparation | |
|---|---|---|---|
| | Example | Example | |
| | Polishing Slurry | Polishing Pad | MRR (Å/min) |
| Example 1 | Prep. Example 1 | Prep. Example A | 311 |
| Example 2 | Prep. Example 1 | Prep. Example B | 303 |
| Example 3 | Prep. Example 1 | Prep. Example C | 290 |
| Comparative | Prep. Example 1 | Comp. Example A | 89 |
| Example 1 | | | |
| Comparative | Prep. Example 2 | Comp. Example A | 140 |
| Example 2 | | | |
| Comparative | Comp. Example 1 | Prep. Example A | 80 |
| Example 3 | | | |
| Comparative | Comp. Example 1 | Prep. Example B | 110 |
| Example 4 | | | |
| Comparative | Comp. Example 1 | Prep. Example C | 120 |
| Example 5 | | | |

Referring to Table 2, when the chemical/mechanical polishing is respectively performed according to Examples 1 to 3, the polishing rate is significantly increased in comparison to when the chemical/mechanical polishing is respectively performed according to Comparative Examples 1 to 5. In addition, as an elastic modulus at room temperature of the polishing pad decreases, the polishing rate significantly increases.

Accordingly, when the chemical/mechanical polishing is performed by using polishing slurry including nano-abrasive, a polishing rate is improved within a predetermined range of a room temperature elastic modulus of a polishing pad, and particularly, as the room temperature elastic modulus decreases, the polishing rate significantly increases.

On the contrary, when the chemical/mechanical polishing is performed by using polishing slurry including silica abrasives according to Comparative Examples 3 to 5, as the elastic modulus at room temperature of the polishing pad decreases, the polishing rate also degrades or decreases.

Accordingly, when the chemical/mechanical polishing is performed by using nano-abrasives such as carbon nano-abrasives instead of large-sized abrasives such as silica, a polishing pad having a predetermined elastic modulus at room temperature may be effectively used.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A chemical mechanical polishing method comprising:
preparing a polishing pad including a polishing surface, the polishing surface having an elastic modulus at room temperature of about 300 megapascals to about 400 megapascals,
positioning a semiconductor structure having a surface, wherein the structure surface and the polishing surface of the polishing pad face each other,
supplying polishing slurry between the surface of the semiconductor structure and the polishing surface of the polishing pad, the polishing slurry including nano-abrasive having an average particle diameter of less than about 10 nanometers, and
contacting the surface of the semiconductor surface with the polishing surface of the polishing pad to polish the structure surface with the polishing slurry.

2. The chemical mechanical polishing method of claim 1, wherein the polishing surface of the polishing pad has an elastic modulus at room temperature of about 340 megapascals to about 360 megapascals.

3. The chemical mechanical polishing method of claim 1, wherein
the polishing surface of the polishing pad has an average pore size of about 20 micrometers to about 40 micrometers, and a pore density of about 50 percent to about 60 percent.

4. The chemical mechanical polishing method of claim 1, wherein the polishing surface of the polishing pad has a hardness of about 50 Shore D to about 55 Shore D.

5. The chemical mechanical polishing method of claim 1, wherein the average particle diameter of the nano-abrasive is greater than or equal to about 0.1 nanometers and less than about 5 nanometers.

6. The chemical mechanical polishing method of claim 1, wherein the nano-abrasive comprise carbon nano-abrasive.

7. The chemical mechanical polishing method of claim 6, wherein the carbon nano-abrasive comprise fullerene or a fullerene derivative, graphene, graphite, carbon nanotube, carbon dot, or a combination thereof.

8. The chemical mechanical polishing method of claim 7, wherein
the carbon nano-abrasive comprise hydrophilic fullerene having at least one hydrophilic functional group, and
the hydrophilic functional group comprises at least one of a hydroxyl group, an amino group, a carbonyl group, a carboxyl group, a sulfhydryl group, or a phosphate group.

9. The chemical mechanical polishing method of claim 7, wherein the carbon nano-abrasive comprise hydroxyl fullerene represented by Cₓ(OH)_{y} wherein x is 60, 70, 74, 76, or 78, and y is an integer from 12 to 44).

10. The chemical mechanical polishing method of claim 1, wherein in the polishing of the surface of the semiconductor structure the temperature of the polishing pad does not substantially change.

11. A method of manufacturing a semiconductor device comprising the chemical mechanical polishing method of claim 1.

12. The method of claim 11, wherein the chemical mechanical polishing method is applied to polishing a metal layer of the semiconductor structure.

13. A polishing pad comprising a polishing surface, the polishing surface having an elastic modulus at room temperature of about 300 megapascals to about 400 megapascals.

14. The polishing pad of claim 13, in combination with the polishing slurry comprising nano-abrasives having an average particle diameter of less than about 10 nanometers.

15. The polishing pad of claim 14, wherein as a polishing rate of a metal layer using the polishing pad increases the elastic modulus at room temperature of the polishing surface decreases.

16. The polishing pad of claim 13, wherein the polishing surface has an elastic modulus at room temperature of about 340 megapascals to about 360 megapascals.

17. The polishing pad of claim 13, wherein
the polishing surface has an average pore size of about 20 micrometers to about 40 micrometers and a pore density of about 50 percent to about 55 percent.

18. The polishing pad of claim 13, wherein the polishing surface has a hardness of about 50 Shore D to about 55 Shore D.

19. The polishing pad of claim 13, wherein the polishing pad comprises:
a first layer comprising the polishing surface, and
a second layer having an elastic modulus at room temperature greater than the elastic modulus at room temperature of the first layer.

20. A chemical mechanical polishing device comprising
a rotatable platen,
the polishing pad of claim 13, the polishing pad being disposed on the platen, and
a polishing slurry supplier for supplying polishing slurry, the polishing slurry supplier being disposed adjacent to the polishing pad.
